(19) United States
(12) Patent Application Publication
(10) Pub. No.: US 2023/0208388 A1
(43) Pub. Date: Jun. 29, 2023

(54) VIBRATOR DEVICE AND METHOD FOR MANUFACTURING VIBRATOR DEVICE

(71) Applicant: SEIKO EPSON CORPORATION, Tokyo (JP)

(72) Inventor: Koichi Mizugaki, Suwa-shi (JP)

(21) Appl. No.: 18/086,955

(22) Filed: Dec. 22, 2022

(30) Foreign Application Priority Data
Dec. 24, 2021 (JP) 2021-210442

(51) Int. Cl. H03H 9/05; H03H 3/02; H03H 9/10; H03H 9/19

(52) U.S. Cl. CPC H03H 9/0547; H03H 3/02; H03H 9/1021; H03H 9/19; H03H 2003/022

(57) ABSTRACT

A vibrator device includes: a base having a first surface and a second surface in a front-back relationship with each other; a circuit element located at a first surface side of the base and having a third surface at the first surface side and a fourth surface in a front-back relationship with the third surface; a vibrator element located at a fourth surface side of the circuit element; a first bonding member that bonds the base to the circuit element; a second bonding member that bonds the circuit element to the vibrator element; and a lid bonded to the base so as to form a cavity that accommodates the circuit element and the vibrator element between the lid and the base, in which at least a part of the second bonding member overlaps the first bonding member in a plan view of the circuit element.

The present application is based on, and claims priority from JP Application Serial Number 2021-210442, filed Dec. 24, 2021, the disclosure of which is hereby incorporated by reference herein in its entirety.

### BACKGROUND

### 1. Technical Field

The present disclosure relates to a vibrator device and a method for manufacturing a vibrator device.

### 2. Related Art

JP-A-2012-134792 discloses a piezoelectric oscillator including a piezoelectric vibrator element, an IC chip, a base that holds the piezoelectric vibrator element and the IC chip, and a lid bonded to the base to seal the piezoelectric vibrator element and the IC chip, in which an electrode pad formed on the base and a first coupling terminal formed on one main surface of the IC chip are bonded to each other via a metal bump, a second coupling terminal formed on the other main surface of the IC chip and a coupling electrode of the piezoelectric vibrator element are bonded to each other via a metal bump, and the first coupling terminal and the second coupling terminal are formed at positions not overlapping the IC chip. That is, in JP-A-2012-134792, a bonding portion between the base and the IC chip and a bonding portion between the IC chip and the piezoelectric vibrator element are formed at positions not overlapping each other in a plan view. In other words, a gap is formed between the base and the IC chip at a position overlapping the bonding portion between the IC chip and the piezoelectric vibrator element in the plan view.

In recent years, there is a demand for further reduction in size and thickness of a piezoelectric oscillator. Accordingly, a reduction in thickness of an IC chip accommodated in the piezoelectric oscillator has been developed. However, in the piezoelectric oscillator disclosed in JP-A-2012-134792, since the bonding portion between the base and the IC chip and the bonding portion between the IC chip and the piezoelectric vibrator element are formed at positions not overlapping each other in the plan view, when the bonding portion between the IC chip and the piezoelectric vibrator element is pressed in a case of bonding the piezoelectric vibrator element to the IC chip, the IC chip is bent toward the base due to a pressing force. When the IC chip is bent toward the base, the bonding portion between the IC chip and the piezoelectric vibrator element cannot be effectively pressed, and thus bonding reliability between the IC chip and the piezoelectric vibrator element may be reduced.

### SUMMARY

A vibrator device includes: a base having a first surface and a second surface in a front-back relationship with each other; a circuit element located at a first surface side of the base and having a third surface at the first surface side and a fourth surface in a front-back relationship with the third surface; a vibrator element located at a fourth surface side of the circuit element; a first bonding member disposed between the base and the circuit element and configured to bond the base to the circuit element; a second bonding member disposed between the circuit element and the vibrator element and configured to bond the circuit element to the vibrator element; and a lid bonded to the base so as to form a cavity that accommodates the circuit element and the vibrator element between the lid and the base, in which at least a part of the second bonding member overlaps the first bonding member in a plan view of the circuit element.

A method for manufacturing a vibrator device including a base, a circuit element, a vibrator element, and a lid bonded to the base so as to form a cavity that accommodates the circuit element and the vibrator element between the lid and the base, the method includes: preparing the base having a first surface and a second surface in a front-back relationship with each other; disposing a first bonding member at the first surface of the base; disposing the circuit element at a first surface side, the circuit element having a third surface located at the first surface side and a fourth surface in a front-back relationship with the third surface; bonding the circuit element to the base via the first bonding member; disposing a second bonding member on the fourth surface of the circuit element; disposing the vibrator element at a fourth surface side of the circuit element; bonding the vibrator element to the circuit element via the second bonding member; and forming the cavity that accommodates the circuit element and the vibrator element by bonding the lid to the base, in which at least a part of the second bonding member overlaps the first bonding member in a plan view of the circuit element.

A method for manufacturing a vibrator device including a base, a circuit element, a vibrator element, and a lid bonded to the base so as to form a cavity that accommodates the circuit element and the vibrator element between the lid and the base, the method includes: preparing the base having a first surface and a second surface in a front-back relationship with each other; disposing a first bonding member at the first surface of the base; disposing the circuit element at a first surface side, the circuit element having a third surface located at the first surface side and a fourth surface in a front-back relationship with the third surface; bonding the circuit element to the base via the first bonding member; disposing a second bonding member on the vibrator element; disposing the vibrator element at a fourth surface side of the circuit element; bonding the vibrator element to the circuit element via the second bonding member; and forming the cavity that accommodates the circuit element and the vibrator element by bonding the lid to the base, in which at least a part of the second bonding member overlaps the first bonding member in a plan view of the circuit element.

### BRIEF DESCRIPTION OF THE DRAWINGS

FIG. 1 is a cross-sectional view of a vibrator device according to a first embodiment.

FIG. 2 is a plan view of the vibrator device according to the first embodiment.

FIG. 3 is a cross-sectional view taken along a line A-A in FIG. 2.

FIG. 4 is a plan view of a base shown in FIG. 2.

FIG. 5 is a plan view of a circuit element and the base that are shown in FIG. 2.

FIG. 6 is a diagram showing a process of manufacturing the vibrator device according to the first embodiment.

FIG. 7 is a cross-sectional view illustrating a method for manufacturing a vibrator device.

FIG. 8 is a cross-sectional view illustrating the method for manufacturing a vibrator device.

FIG. 9 is a cross-sectional view illustrating the method for manufacturing a vibrator device.

FIG. 10 is a cross-sectional view illustrating the method for manufacturing a vibrator device.

FIG. 11 is a cross-sectional view illustrating the method for manufacturing a vibrator device.

FIG. 12 is a cross-sectional view illustrating the method for manufacturing a vibrator device.

FIG. 13 is a cross-sectional view illustrating the method for manufacturing a vibrator device.

FIG. 14 is a cross-sectional view illustrating the method for manufacturing a vibrator device.

FIG. 15 is a cross-sectional view illustrating the method for manufacturing a vibrator device.

FIG. 16 is a cross-sectional view illustrating the method for manufacturing a vibrator device.

FIG. 17 is a plan view of a vibrator device according to a second embodiment.

FIG. 18 is a cross-sectional view taken along a line B-B in FIG. 17.

FIG. 19 is a plan view of a circuit element and a base that are shown in FIG. 17.

FIG. 20 is a diagram showing a process of manufacturing a vibrator device according to a third embodiment.

FIG. 21 is a cross-sectional view illustrating a method for manufacturing a vibrator device.

FIG. 22 is a cross-sectional view illustrating the method for manufacturing a vibrator device.

FIG. 23 is a cross-sectional view illustrating the method for manufacturing a vibrator device.

FIG. 24 is a cross-sectional view illustrating the method for manufacturing a vibrator device.

### DESCRIPTION OF EXEMPLARY EMBODIMENTS

Next, embodiments of the present disclosure will be described with reference to the drawings.

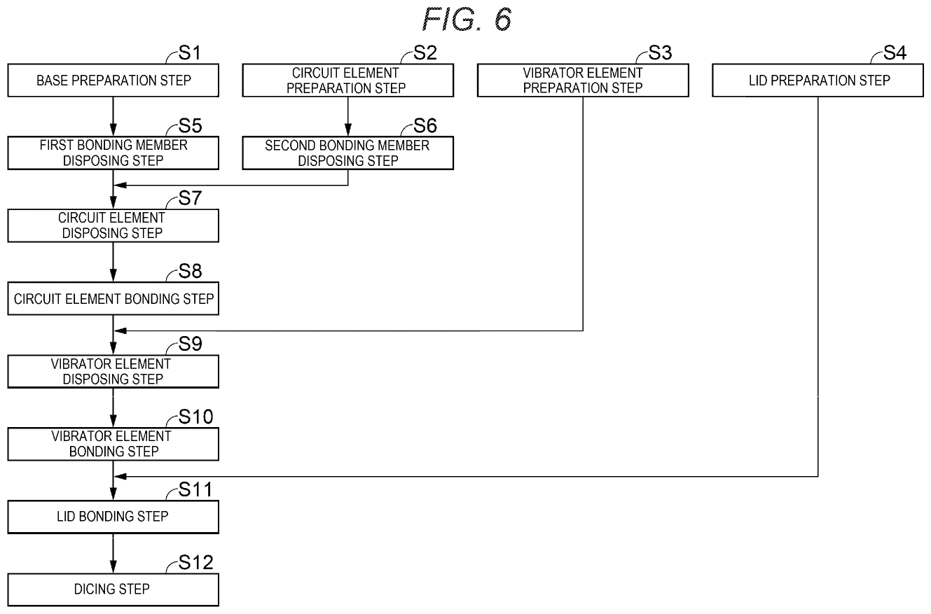

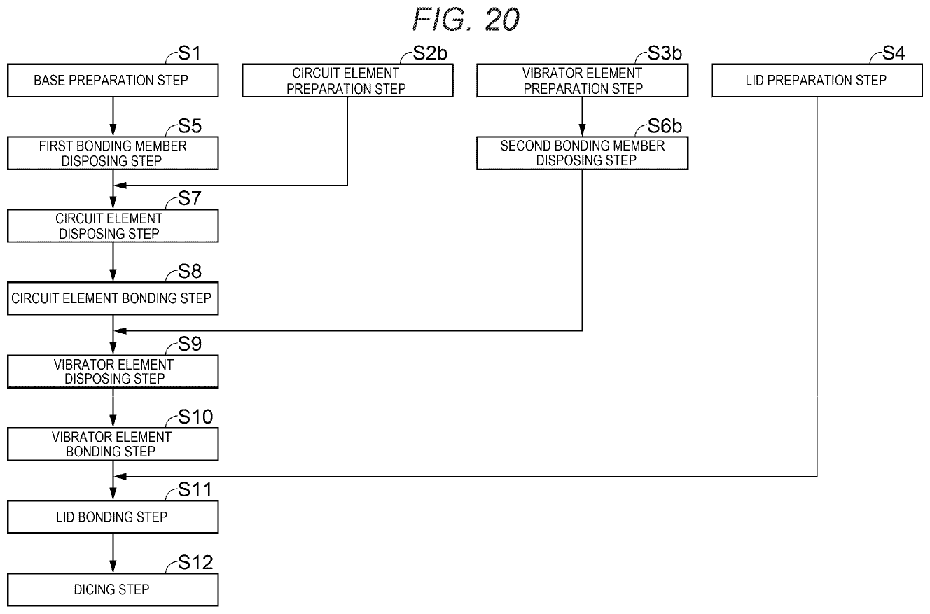

For convenience of description, in each drawing excluding FIGS. 6 and 20, an X axis, a Y axis, and a Z axis are illustrated as three axes orthogonal to one another. A direction along the X axis is referred to as an “X direction”, a direction along the Y axis is referred to as a “Y direction”, and a direction along the Z axis is referred to as a “Z direction”. An arrow tip side in each axial direction is also referred to as a “plus side”, and an arrow proximal end side is also referred to as a “minus side”. For example, the Y direction refers to both a plus side in the Y direction and a minus side in the Y direction. A plus side in the Z direction is also referred to as “upper”, and a minus side in the Z direction is also referred to as “lower”. A plan view seen from the Z direction is also simply referred to as a “plan view”.

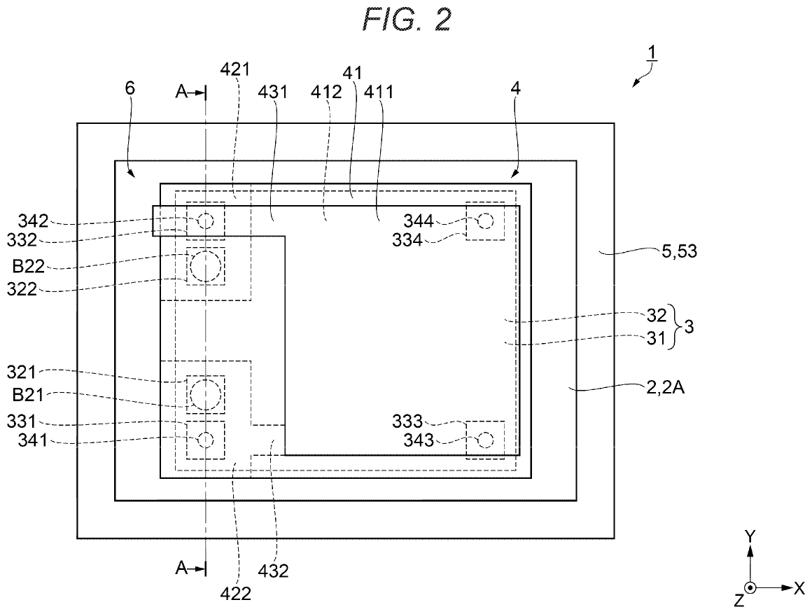

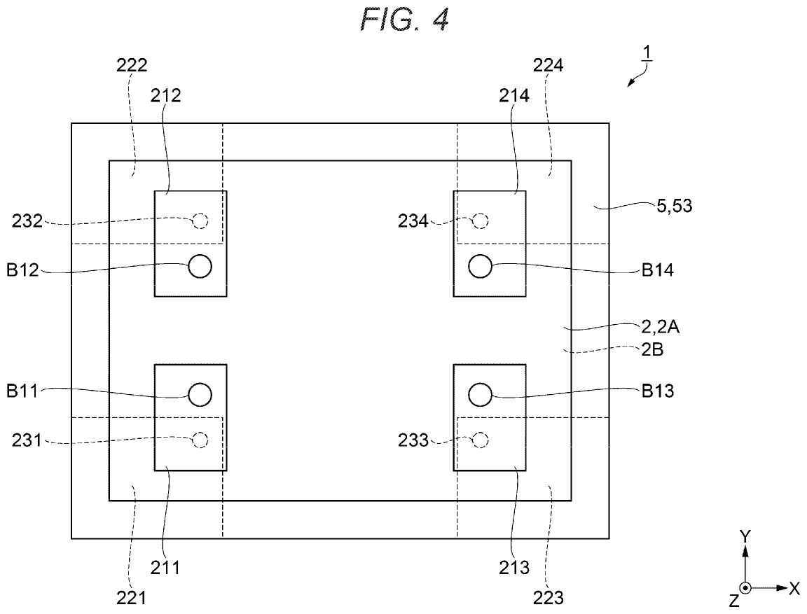

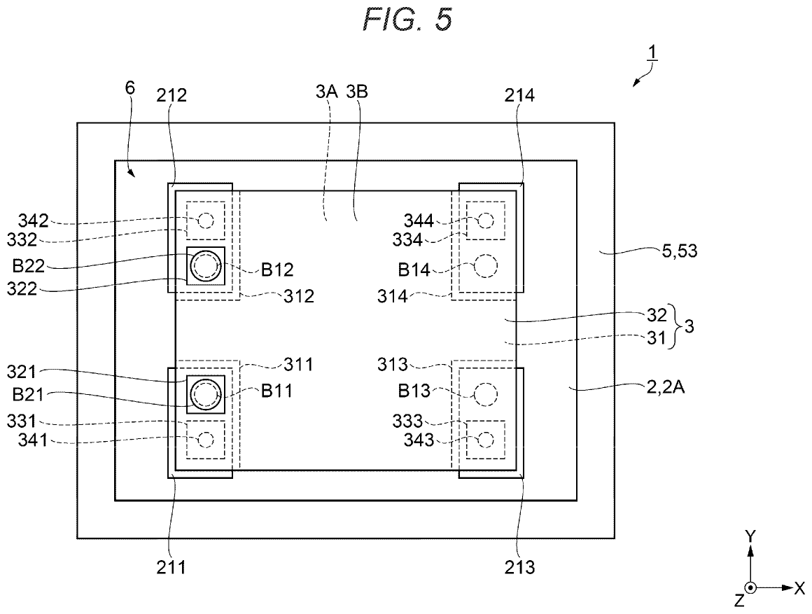

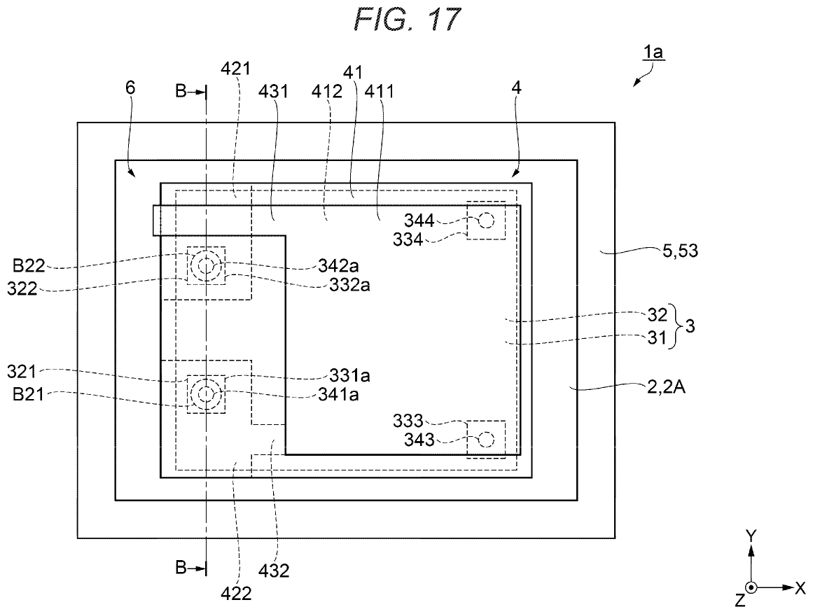

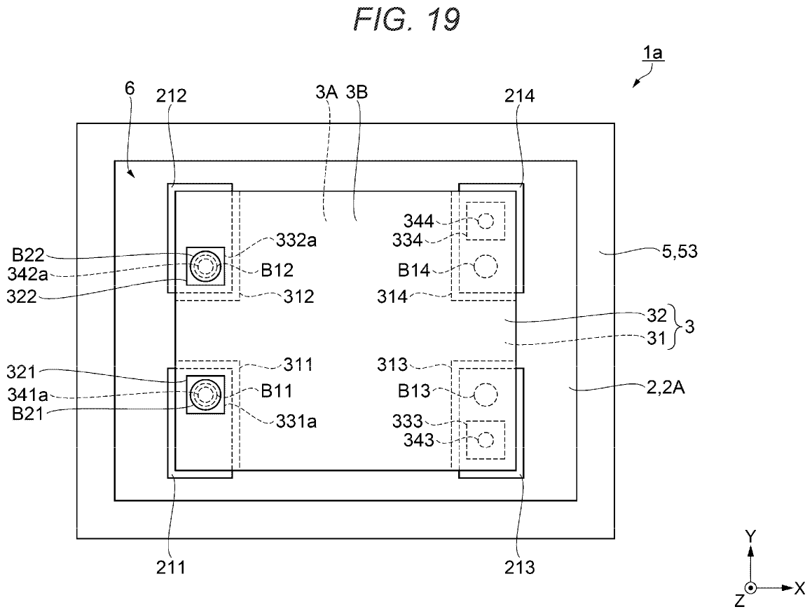

For convenience of description, a top plate of a lid 5 is not illustrated in FIGS. 2 and 17. In FIG. 4, illustration of a circuit element 3, a vibrator element 4, and the top plate of the lid 5 is omitted. In FIGS. 5 and 19, illustration of the vibrator element 4 and the top plate of the lid 5 is omitted.

### 1. First Embodiment

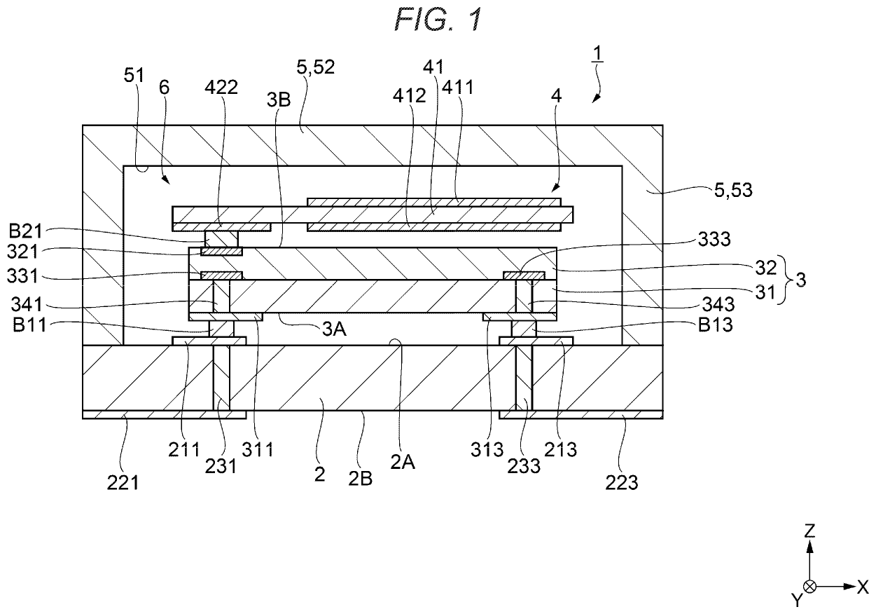

A vibrator device 1 according to a first embodiment will be described with reference to FIGS. 1 to 5. In the present embodiment, the vibrator device 1 is an oscillator. However, the vibrator device 1 may not be an oscillator. For example, the vibrator device 1 may be an inertial sensor.

As shown in FIGS. 1, 2, and 3, the vibrator device 1 includes a base 2, the circuit element 3, the vibrator element 4, and the lid 5. The base 2, the circuit element 3, and the vibrator element 4 are stacked in this order along the Z direction. The lid 5 is bonded to the base 2. When the base 2 and the lid 5 are bonded to each other, a cavity 6, which is an accommodation space that accommodates the circuit element 3 and the vibrator element 4, is formed between the base 2 and the lid 5.

First, the base 2 will be described.

As shown in FIGS. 1, 3, and 4, in the present embodiment, the base 2 has a flat plate shape. The base 2 has a first surface 2A and a second surface 2B in a front-back relationship with each other. In the present embodiment, the first surface 2A of the base 2 is an upper surface of the base 2. The second surface 2B of the base 2 is a lower surface of the base 2.

In the present embodiment, the base 2 is a semiconductor substrate made of silicon. The material for forming the base 2 is not particularly limited. For example, the base 2 may be a semiconductor substrate made of a semiconductor material other than silicon, or may be a ceramic substrate made of alumina or the like.

A plurality of base electrodes 211, 212, 213, and 214 are provided on the first surface 2A of the base 2. The base electrodes 211, 212, 213, and 214 are electrically coupled to the circuit element 3 located at a first surface 2A side of the base 2.

A plurality of external electrodes 221, 222, 223, and 224 are provided on the second surface 2B of the base 2. The external electrodes 221, 222, 223, and 224 are electrically coupled to the outside. That is, the vibrator device 1 is electrically coupled to the outside via the external electrodes 221, 222, 223, and 224. The external electrodes 221, 222, 223, and 224 are, for example, a ground terminal for coupling to a ground potential, an external output terminal for outputting a clock signal or the like, a power supply terminal for coupling to a power supply, or an output enable terminal for controlling output from the external output terminal.

The base 2 is provided with a plurality of base through electrodes 231, 232, 233, and 234 penetrating between the first surface 2A and the second surface 2B of the base 2. The base through electrodes 231, 232, 233, and 234 are each a through electrode formed by using a conductor to fill a through hole that penetrates the base 2. The base through electrodes 231, 232, 233, and 234 each may have a hollow portion as long as functions of the base through electrodes are not impaired.

The base through electrode 231 is disposed to overlap the base electrode 211 and the external electrode 221 in the plan view, and electrically couples the base electrode 211 to the external electrode 221. The base through electrode 232 is disposed to overlap the base electrode 212 and the external electrode 222 in the plan view, and electrically couples the base electrode 212 to the external electrode 222. The base through electrode 233 is disposed to overlap the base electrode 213 and the external electrode 223 in the plan view, and electrically couples the base electrode 213 to the external electrode 223. The base through electrode 234 is disposed to overlap the base electrode 214 and the external electrode 224 in the plan view, and electrically couples the base electrode 214 to the external electrode 224.

Next, the circuit element 3 will be described.

In the present embodiment, the circuit element 3 is an integrated circuit (IC) chip.

As shown in FIGS. 1, 3, and 5, the circuit element 3 is located at the first surface 2A side of the base 2. The circuit element 3 has a flat plate shape. The circuit element 3 has a third surface 3A and a fourth surface 3B in a front-back relationship with each other. In the present embodiment, the third surface 3A of the circuit element 3 is a lower surface of the circuit element 3 and is a surface facing the first surface 2A of the base 2. The fourth surface 3B of the circuit element 3 is an upper surface of the circuit element 3.

The circuit element 3 includes an element substrate 31 and a circuit unit 32.

The element substrate 31 is a semiconductor substrate made of silicon. Regarding the material for forming the element substrate 31, the element substrate 31 may be a semiconductor substrate made of a semiconductor material other than silicon.

The circuit unit 32 is an integrated circuit in which active elements such as a plurality of transistors (not shown) are electrically coupled to each other by a wire (not shown). The circuit unit 32 includes an oscillation circuit that oscillates the vibrator element 4 and that generates an output signal such as a clock signal. In addition to the oscillation circuit, the circuit unit 32 may include a temperature compensation circuit that corrects a vibration characteristic of the vibrator element 4 according to a temperature change, a processing circuit that processes an output signal from the oscillation circuit, an electrostatic protection circuit, and the like.

In the present embodiment, the circuit unit 32 is provided on an upper surface of the element substrate 31. A lower surface of the element substrate 31 is the third surface 3A of the circuit element 3. An upper surface of the circuit unit 32 is the fourth surface 3B of the circuit element 3.

A plurality of first element electrodes 311, 312, 313, and 314 are provided on the lower surface of the element substrate 31, that is, the third surface 3A of the circuit element 3. The first element electrodes 311, 312, 313, and 314 are electrically coupled to the base electrodes 211, 212, 213, and 214 provided on the first surface 2A of the base 2, respectively.

A plurality of second element electrodes 321 and 322 are provided on the upper surface of the circuit unit 32, that is, the fourth surface 3B of the circuit element 3. The second element electrodes 321 and 322 are electrically coupled to the circuit unit 32. The second element electrodes 321 and 322 are electrically coupled to the vibrator element 4 located at a fourth surface 3B side of the circuit element 3.

A plurality of third element electrodes 331, 332, 333, and 334 are provided on a lower surface of the circuit unit 32. The third element electrodes 331, 332, 333, and 334 are electrically coupled to the circuit unit 32.

In addition, the circuit element 3 is provided with a plurality of element through electrodes 341, 342, 343, and 344 penetrating between the lower surface and the upper surface of the element substrate 31. The element through electrodes 341, 342, 343, and 344 are each a through electrode formed by using a conductor to fill a through hole that penetrates the element substrate 31. The element through electrodes 341, 342, 343, and 344 each may have a hollow portion as long as functions of the element through electrodes are not impaired.

The element through electrode 341 is disposed to overlap the first element electrode 311 and the third element electrode 331 in the plan view, and electrically couples the first element electrode 311 to the third element electrode 331. The element through electrode 342 is disposed to overlap the first element electrode 312 and the third element electrode 332 in the plan view, and electrically couples the first element electrode 312 to the third element electrode 332. The element through electrode 343 is disposed to overlap the first element electrode 313 and the third element electrode 333 in the plan view, and electrically couples the first element electrode 313 to the third element electrode 333. The element through electrode 344 is disposed to overlap the first element electrode 314 and the third element electrode 334 in the plan view, and electrically couples the first element electrode 314 to the third element electrode 334.

Next, the vibrator element 4 will be described.

As shown in FIGS. 1, 2, and 3, the vibrator element 4 is located at the fourth surface 3B side of the circuit element 3. The vibrator element 4 includes a vibrator substrate 41 and electrodes disposed on surfaces of the vibrator substrate 41. The electrodes disposed on the surfaces of the vibrator substrate 41 include a pair of excitation electrodes 411 and 412, a pair of coupling electrodes 421 and 422, and a pair of lead-out wires 431 and 432.

The vibrator substrate 41 has a flat plate shape. In the present embodiment, the vibrator substrate 41 is an SC-cut quartz crystal substrate.

The excitation electrode 411 is disposed on an upper surface of the vibrator substrate 41. The excitation electrode 412 is disposed on a lower surface of the vibrator substrate 41. The excitation electrode 411 and the excitation electrode 412 are disposed at positions facing each other with the vibrator substrate 41 interposed therebetween. The coupling electrodes 421 and 422 are disposed on the lower surface of the vibrator substrate 41. The lead-out wire 431 is disposed on the upper surface and a side surface of the vibrator substrate 41, and electrically couples the excitation electrode 411 to the coupling electrode 421. The lead-out wire 432 is disposed on the lower surface of the vibrator substrate 41 and electrically couples the excitation electrode 412 to the coupling electrode 422.

By applying a drive signal to the excitation electrodes 411 and 412 via the coupling electrodes 421 and 422 and the lead-out wires 431 and 432, it is possible to excite thickness-shear vibration in the vibrator substrate 41 sandwiched between the excitation electrodes 411 and 412.

A configuration of the vibrator element 4 is not limited to the above-described configuration. For example, the vibrator element 4 is not limited to a flat plate-shaped vibrator element that vibrates in a thickness-shear mode. The vibrator element 4 may be, for example, a vibrator element in which a plurality of vibrating arms perform flexural vibration in an in-plane direction, or a vibrator element in which a plurality of vibrating arms perform flexural vibration in an out-of-plane direction. The vibrator element 4 may be a vibrator element in which, for example, an X-cut quartz crystal substrate, a Y-cut quartz crystal substrate, a Z-cut quartz crystal substrate, a BT-cut quartz crystal substrate, an AT-cut quartz crystal substrate, or an ST-cut quartz crystal substrate is used as the vibrator substrate 41. The vibrator element 4 may be, for example, a vibrator element in which a piezoelectric body other than a quartz crystal is used. Further, the vibrator element 4 may be, for example, a surface acoustic wave (SAW) resonator, or a micro-electro-mechanical systems (MEMS) vibrator in which a piezoelectric element is disposed on a semiconductor substrate made of silicon or the like.

The base 2, the circuit element 3, and the vibrator element 4 are briefly described above.

Next, first bonding members B11, B12, B13, and B14 for bonding the base 2 to the circuit element 3 and second bonding members B21 and B22 for bonding the circuit element 3 to the vibrator element 4 will be described.

First, the first bonding members B11, B12, B13, and B14 will be described.

As shown in FIGS. 1, 3, and 5, the first bonding members B11, B12, B13, and B14 are disposed between the base 2 and the circuit element 3. Specifically, the first bonding members B11, B12, B13, and B14 are respectively disposed between the base electrodes 211, 212, 213, and 214 provided on the first surface 2A, which is the upper surface of the base 2, and the first element electrodes 311, 312, 313, and 314 provided on the third surface 3A, which is the lower surface of the circuit element 3.

The base 2 and the circuit element 3 are mechanically coupled to each other via the first bonding members B11, B12, B13, and B14.

In the present embodiment, the first bonding members B11, B12, B13, and B14 are metal bumps. The metal bumps as the first bonding members B11, B12, B13, and B14 are also referred to as first metal bumps.

When the first bonding members B11, B12, B13, and B14 are metal bumps, the base electrodes 211, 212, 213, and 214 are electrically coupled to the first element electrodes 311, 312, 313, and 314, respectively. That is, when the first bonding members B11, B12, B13, and B14 are metal bumps, the base 2 and the circuit element 3 are mechanically and electrically coupled to each other.

Next, the second bonding members B21 and B22 will be described.

As shown in FIGS. 1, 3, and 5, the second bonding members B21 and B22 are disposed between the circuit element 3 and the vibrator element 4. Specifically, the second bonding member B21 is disposed between the second element electrode 321 provided on the fourth surface 3B, which is the upper surface of the circuit element 3, and the coupling electrode 422 provided on a surface facing the fourth surface 3B, which is a lower surface of the vibrator element 4. The second bonding member B22 is disposed between the second element electrode 322 provided on the upper surface of the circuit element 3 and the coupling electrode 421 provided on the lower surface of the vibrator element 4.

The circuit element 3 and the vibrator element 4 are mechanically coupled to each other via the second bonding members B21 and B22.

In the present embodiment, the second bonding members B21 and B22 are metal bumps. The metal bumps as the second bonding members B21 and B22 are also referred to as second metal bumps.

When the second bonding members B21 and B22 are metal bumps, the second element electrodes 321 and 322 are respectively electrically coupled to the coupling electrodes 421 and 422. That is, when the second bonding members B21 and B22 are metal bumps, the circuit element 3 and the vibrator element 4 are mechanically and electrically coupled to each other.

The metal bumps used as the first bonding members B11, B12, B13, and B14 and the second bonding members B21 and B22 are not particularly limited as long as conductivity and bondability are provided. For example, a metal bump such as a gold bump, a silver bump, a copper bump, or a solder bump can be used.

The first bonding members B11, B12, B13, and B14 and the second bonding members B21 and B22 may not be metal bumps.

The first bonding members B11, B12, B13, and B14 and the second bonding members B21 and B22 may be, for example, insulating adhesives. However, conductive members such as metal bumps are preferably used as the first bonding members B11, B12, B13, and B14 and the second bonding members B21 and B22. When the first bonding members B11, B12, B13, and B14 and the second bonding members B21 and B22 are insulating adhesives, it is necessary to further provide a wire for electrically coupling the base 2 and the circuit element 3 and a wire for electrically coupling the circuit element 3 and the vibrator element 4.

The first bonding members B11, B12, B13, and B14 and the second bonding members B21 and B22 may also be, for example, conductive adhesives. However, the first bonding members B11, B12, B13, and B14 and the second bonding members B21 and B22 are preferably metal bumps. The metal bump has a variation in a bonding area smaller than that of a conductive adhesive, and thus a short circuit between electrodes is less likely to occur. In addition, the metal bump can be bonded in a time shorter than that of the conductive adhesive.

The circuit element 3 may be provided with a temperature sensor or a heater. When a heat insulation property between the circuit element 3 provided with the temperature sensor or the heater and the outside of the vibrator device 1 is low, there are problems such as a decrease in temperature compensation accuracy by the circuit element 3 and difficulty in maintaining a temperature of the vibrator element 4 constant.

Since the circuit element 3 is bonded to the base 2, it is necessary to improve a heat insulation property between the circuit element 3 and the base 2 in order to improve the heat insulation property between the circuit element 3 and the outside of the vibrator device 1.

In the present embodiment, a gap is formed between the circuit element 3 and the base 2 in a region of the circuit element 3 in which the first bonding members B11, B12, B13, and B14 do not overlap the circuit element 3 in the plan view. That is, in the region of the circuit element 3 in which the first bonding members B11, B12, B13, and B14 do not overlap the circuit element 3 in the plan view, the circuit element 3 floats above the base 2.

When the first bonding members B11, B12, B13, and B14 are metal bumps, a bonding area between the base 2 and the circuit element 3 can be smaller than in a case of adhesives. That is, when the first bonding members B11, B12, B13, and B14 are metal bumps, it is possible to widen the region in which the gap is formed between the circuit element 3 and the base 2 in the plan view. By widening the region in which the gap is formed between the circuit element 3 and the base 2, it is possible to improve the heat insulation property between the circuit element 3 and the outside of the vibrator device 1.

Next, a positional relationship between the first bonding members B11 and B12 and the second bonding members B21 and B22 will be described.

As shown in FIGS. 1, 3, and 5, the first bonding members B11 and B12 respectively overlap the second bonding members B21 and B22 in the plan view of the circuit element 3.

In the present embodiment, since the first bonding members B11 and B12 respectively overlap the second bonding members B21 and B22 in the plan view, the circuit element 3 is supported from below by the first bonding members B11 and B12 against a pressing force for pressing the second bonding members B21 and B22, and bending of the circuit element 3 is prevented. By preventing the bending of the circuit element 3, it is possible to effectively press the second bonding members B21 and B22. Therefore, it is possible to provide the vibrator device 1 in which bonding reliability between the circuit element 3 and the vibrator element 4 is improved.

In FIG. 5, in the plan view, a part of the second bonding members B21 and B22 respectively overlap the entire first bonding members B11 and B12. Alternatively, the entire second bonding members B21 and B22 may respectively overlap a part of the first bonding members B11 and B12. The entire second bonding members B21 and B22 may overlap the entire first bonding members B11 and B12. A part of the second bonding members B21 and B22 may overlap a part of the first bonding members B11 and B12. In the present embodiment, the second bonding members B21 and B22 respectively overlap the first bonding members B11 and B12. Alternatively, the second bonding members B21 and B22 may overlap, for example, the first bonding members B13 and B14.

In other words, at least a part of the second bonding members B21 and B22 may overlap the first bonding members B11, B12, B13, and B14 in the plan view of the circuit element 3. When at least a part of the second bonding members B21 and B22 overlap the first bonding members B11, B12, B13, and B14 in the plan view of the circuit element 3, it is possible to provide the vibrator device 1 in which the bending of the circuit element 3 is prevented and the bonding reliability between the circuit element 3 and the vibrator element 4 is improved.

Next, a positional relationship between the first bonding members B11, B12, B13, and B14 and the base through electrodes 231, 232, 233, and 234 will be described.

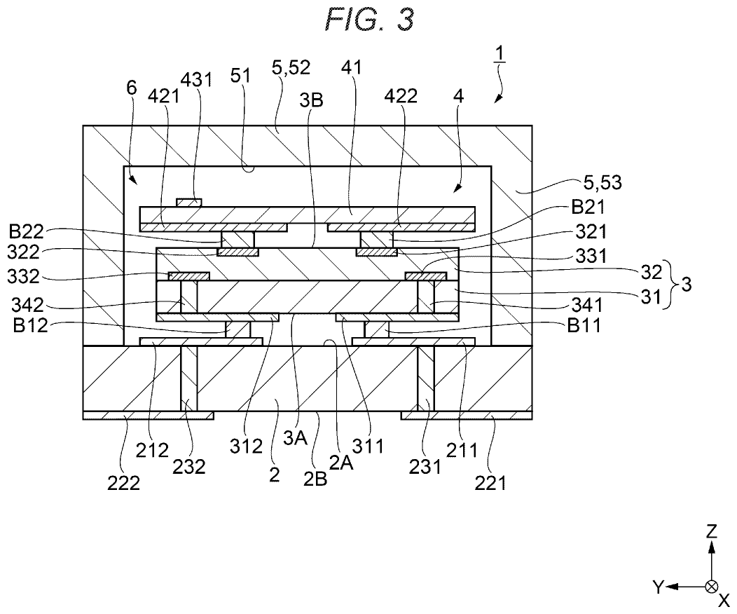

As shown in FIGS. 3 and 4, the first bonding members B11, B12, B13, and B14 do not overlap the base through electrodes 231, 232, 233, and 234 in the plan view, respectively.

As described above, when the heat insulation property between the circuit element 3 provided with the temperature sensor or the heater and the outside of the vibrator device 1 is low, there are problems such as the decrease in temperature compensation accuracy by the circuit element 3 and the difficulty in maintaining the temperature of the vibrator element 4 constant.

The circuit element 3 is electrically coupled to the external electrodes 221, 222, 223, and 224 provided on the second surface 2B of the base 2 via the first bonding members B11, B12, B13, and B14, the base electrodes 211, 212, 213, and 214 provided on the first surface 2A of the base 2, and the base through electrodes 231, 232, 233, and 234. In other words, the base 2 is provided with base wiring portions that electrically couple the first bonding members B11, B12, B13, and B14, the base electrodes 211, 212, 213, and 214, the base through electrodes 231, 232, 233, and 234, and the external electrodes 221, 222, 223, and 224, respectively. The circuit element 3 is coupled to the outside of the vibrator device 1 via the base wiring portions. Specifically, the circuit element 3 is electrically coupled to the first bonding members B11, B12, B13, and B14, which are one end portions of the base wiring portions. The external electrodes 221, 222, 223, and 224, which are the other end portions of the base wiring portions, are exposed to the outside of the vibrator device 1.

In general, the first bonding members B11, B12, B13, and B14, the base electrodes 211, 212, 213, and 214, the base through electrodes 231, 232, 233, and 234, and the external electrodes 221, 222, 223, and 224 are made of a metal, and have a thermal conductivity higher than that of the semiconductor substrate or the ceramic substrate used as the base 2. That is, the base wiring portions, which electrically couple the first bonding members B11, B12, B13, and B14, the base electrodes 211, 212, 213, and 214, the base through electrodes 231, 232, 233, and 234, and the external electrodes 221, 222, 223, and 224, respectively, serve as thermal conduction paths that thermally couple the circuit element 3 to the outside of the vibrator device 1. Therefore, in order to improve the heat insulation property between the circuit element 3 and the outside of the vibrator device 1, it is necessary to increase lengths of the base wiring portions.

In the present embodiment, since the first bonding members B11, B12, B13, and B14 do not overlap the base through electrodes 231, 232, 233, and 234 in the plan view, respectively, the lengths of the base wiring portions can be longer than in a case in which the first bonding members B11, B12, B13, and B14 overlap the base through electrodes 231, 232, 233, and 234, respectively. That is, when the first bonding members B11, B12, B13, and B14 do not overlap the base through electrodes 231, 232, 233, and 234 in the plan view, respectively, it is possible to improve the heat insulation property between the circuit element 3 and the outside of the vibrator device 1.

Next, the lid 5, which is a lid body, will be described.

As shown in FIGS. 1 and 3, in the present embodiment, the lid 5 is disposed at the first surface 2A side of the base 2.

The lid 5 has a box shape including a recessed portion 51. The recessed portion 51 includes an opening portion at a lower surface side of the lid 5. In other words, the lid 5 includes a flat plate-shaped base portion 52 which is a top plate, and a frame-shaped side wall portion 53 which is erected downward from an outer peripheral portion of the base portion 52.

In the present embodiment, the lid 5 is a semiconductor substrate made of silicon. The material for forming the lid 5 is not particularly limited. For example, the lid 5 may be a semiconductor substrate made of a semiconductor material other than silicon, or may be a ceramic substrate made of alumina or the like.

The lid 5 is bonded to the first surface 2A of the base 2 so as to close the opening portion of the recessed portion 51. When the opening portion of the recessed portion 51 is closed by the base 2, the cavity 6 that accommodates the circuit element 3 and the vibrator element 4 is formed between the base 2 and the lid 5. The cavity 6 is, for example, in a depressurized state.

The vibrator device 1 is described above.

Next, a method for manufacturing the vibrator device 1 will be described.

As shown in FIG. 6, the method for manufacturing the vibrator device 1 includes a base preparation step S1, a circuit element preparation step S2, a vibrator element preparation step S3, a lid preparation step S4, a first bonding member disposing step S5, a second bonding member disposing step S6, a circuit element disposing step S7, a circuit element bonding step S8, a vibrator element disposing step S9, a vibrator element bonding step S10, a lid bonding step S11, and a dicing step S12.

Specifically, first, in the base preparation step S1, the circuit element preparation step S2, the vibrator element preparation step S3, and the lid preparation step S4, the base 2, the circuit element 3, the vibrator element 4, and the lid 5 are respectively prepared. Next, the base 2 prepared in the base preparation step S1 and the circuit element 3 prepared in the circuit element preparation step S2 are respectively moved to the first bonding member disposing step S5 and the second bonding member disposing step S6. Next, the base 2 on which the first bonding members B11, B12, B13, and B14 are disposed in the first bonding member disposing step S5 and the circuit element 3 on which the second bonding members B21 and B22 are disposed in the second bonding member disposing step S6 are moved to the circuit element disposing step S7. After completion of the circuit element disposing step S7, the method proceeds to the circuit element bonding step S8. Next, the circuit element 3 and the base 2 that are bonded to each other via the first bonding members B11, B12, B13, and B14 in the circuit element bonding step S8 and the vibrator element 4 prepared in the vibrator element preparation step S3 are moved to the vibrator element disposing step S9. After completion of the vibrator element disposing step S9, the method proceeds to the vibrator element bonding step S10. Next, the base 2, the circuit element 3 bonded to the base 2 via the first bonding members B11, B12, B13, and B14, the vibrator element 4 bonded to the circuit element 3 via the second bonding members B21 and B22 in the vibrator element bonding step S10, and the lid 5 prepared in the lid preparation step S4 are moved to the lid bonding step S11. After completion of the lid bonding step S11, the method proceeds to the dicing step S12. In this manner, the vibrator device 1 shown in FIG. 1 can be obtained.

Hereinafter, these steps will be described in order.

### Base Preparation Step S1

The base preparation step S1 is a step of preparing the base 2 having the first surface 2A and the second surface 2B in a front-back relationship with each other.

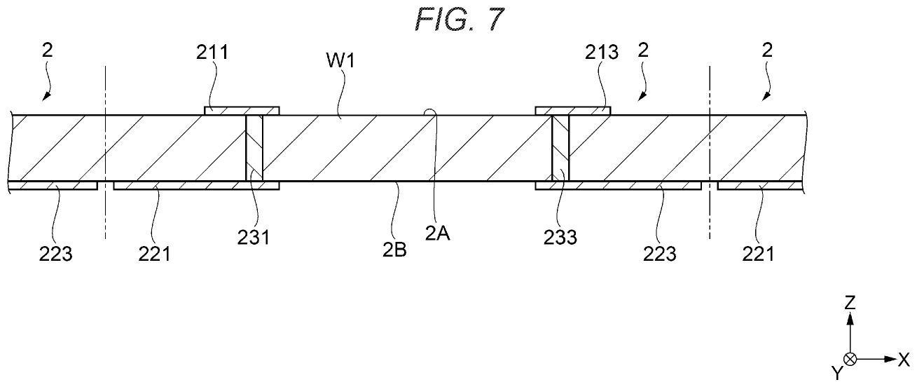

As shown in FIG. 7, a large silicon substrate W1 serving as a base material of the base 2 is prepared. A plurality of bases 2 are collectively formed as the large silicon substrate W1. The large silicon substrate W1 has a flat plate shape, and has the first surface 2A and the second surface 2B in a front-back relationship with each other.

In the base preparation step S1, the base electrodes 211, 212, 213, and 214, the base through electrodes 231, 232, 233, and 234, and the external electrodes 221, 222, 223, and 224 are formed on the base 2 by using a known technique such as a sputtering technique, a photolithographic technique, and an etching technique. Specifically, the base electrodes 211 and 213, the base through electrodes 231 and 233, and the external electrodes 221 and 223 as shown in FIG. 7, and the base electrodes 212 and 214, the base through electrodes 232 and 234, and the external electrodes 222 and 224 as shown in FIGS. 3 and 4 are formed on the base 2.

After the lid bonding step S11 to be described later, the base through electrodes 231, 232, 233, and 234 and the external electrodes 221, 222, 223, and 224 may be formed on the base 2.

### Circuit Element Preparation Step S2

The circuit element preparation step S2 is a step of preparing the circuit element 3.

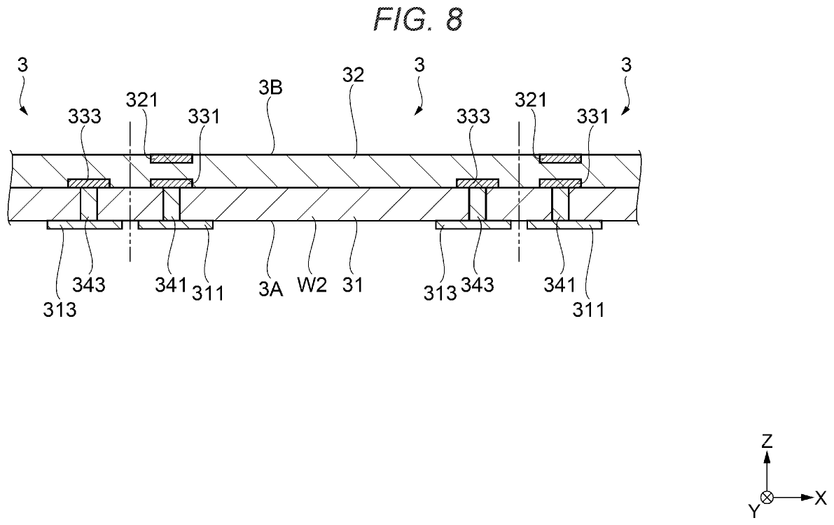

As shown in FIG. 8, a large silicon substrate W2 serving as a base material of the element substrate 31 is prepared. A plurality of circuit elements 3 are collectively formed as the large silicon substrate W2. The large silicon substrate W2 has a flat plate shape.

In the circuit element preparation step S2, the circuit unit 32 is formed on an upper surface of the large silicon substrate W2 by using a known technique such as a sputtering technique, a photolithographic technique, and an etching technique. The second element electrodes 321 and 322 are formed on the upper surface of the circuit unit 32. The third element electrodes 331, 332, 333, and 334 are formed on the lower surface of the circuit unit 32. Specifically, the second element electrode 322 as shown in FIGS. 2 and 3 and the second element electrode 321 are formed on the upper surface of the circuit unit 32 as shown in FIG. 8. The third element electrodes 332 and 334 as shown in FIGS. 2 and 3 and the third element electrodes 331 and 333 as shown in FIG. 8 are formed on the lower surface of the circuit unit 32.

In the circuit element preparation step S2, the element through electrodes 341, 342, 343, and 344 and the first element electrodes 311, 312, 313, and 314 are formed on the element substrate 31 by using a known technique such as a sputtering technique, a photolithographic technique, and an etching technique.

After the circuit unit 32 is formed on the upper surface of the large silicon substrate W2, the element substrate 31 may be thinned by, for example, polishing a lower surface of the large silicon substrate W2. By thinning the element substrate 31, it is possible to reduce a thickness of the circuit element 3. In the case of thinning the element substrate 31, the element through electrodes 341, 342, 343, and 344 and the first element electrodes 311, 312, 313, and 314 are formed after the element substrate 31 is thinned.

### Vibrator Element Preparation Step S3

The vibrator element preparation step S3 is a step of preparing the vibrator element 4.

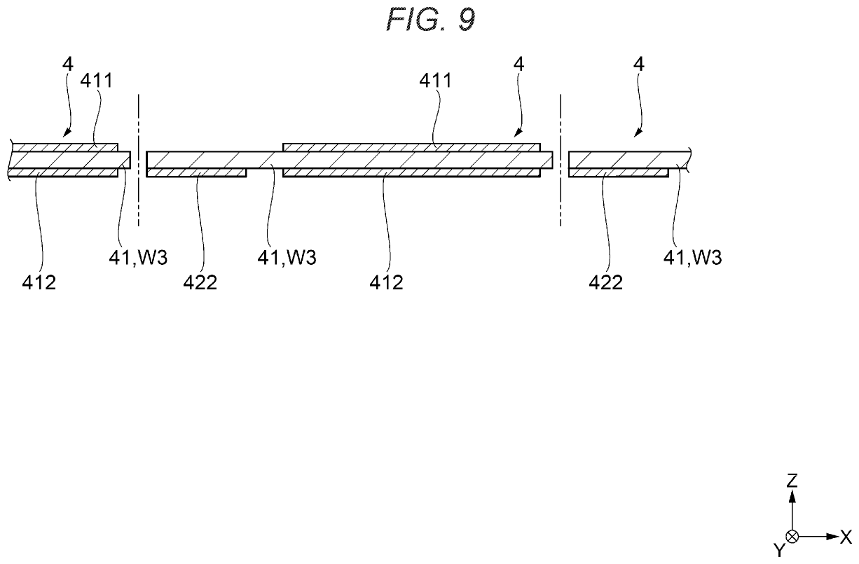

As shown in FIG. 9, a large quartz crystal substrate W3 serving as a base material of the vibrator substrate 41 is prepared. A plurality of vibrator elements 4 are collectively formed as the large quartz crystal substrate W3. The large quartz crystal substrate W3 has a flat plate shape and is adjusted to a desired thickness by polishing processing such as lapping or polishing.

In the vibrator element preparation step S3, the excitation electrodes 411 and 412, the coupling electrodes 421 and 422, and the lead-out wires 431 and 432 are formed on the vibrator substrate 41 by using a known technique such as a sputtering technique, a photolithographic technique, and an etching technique. Specifically, the excitation electrodes 411 and 412 and the coupling electrode 422 as shown in FIG. 9, and the lead-out wires 431 and 432 and the coupling electrode 421 as shown in FIGS. 2 and 3 are formed on the vibrator substrate 41.

In the present embodiment, as shown in FIG. 9, the plurality of vibrator elements 4 formed as the large quartz crystal substrate W3 are diced using a known technique such as a dicing technique or an etching technique after completion of the vibrator element preparation step S3.

### Lid Preparation Step S4

The lid preparation step S4 is a step of preparing the lid 5.

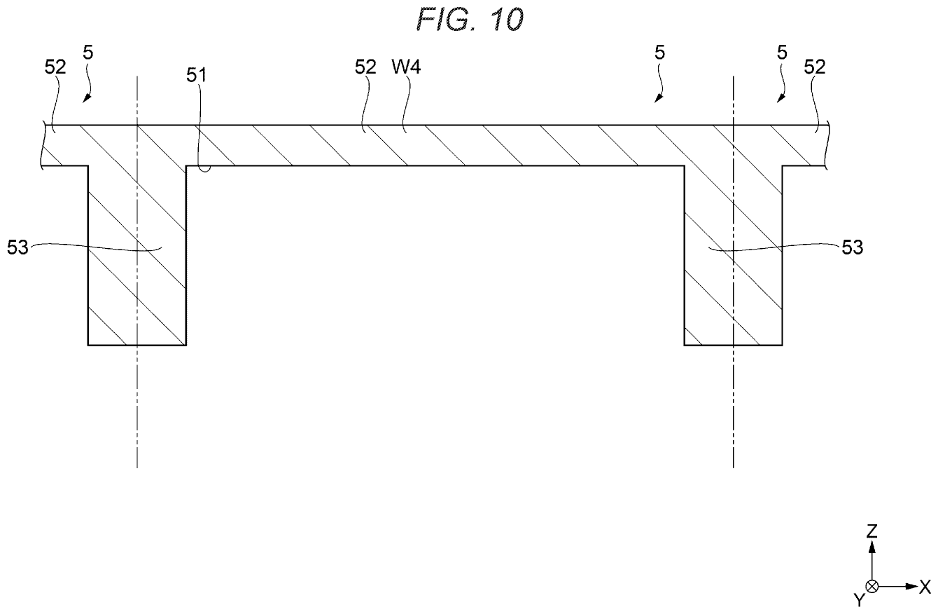

As shown in FIG. 10, a large silicon substrate W4 serving as a base material of the lid 5 is prepared. A plurality of lids 5 are collectively formed as the large silicon substrate W4. The large silicon substrate W4 has a flat plate shape.

In the lid preparation step S4, the recessed portion 51 is formed in the lid 5 by using a known technique such as a photolithographic technique and an etching technique.

### First Bonding Member Disposing Step S5

The first bonding member disposing step S5 is a step of disposing the first bonding members B11, B12, B13, and B14 at the first surface 2A of the base 2.

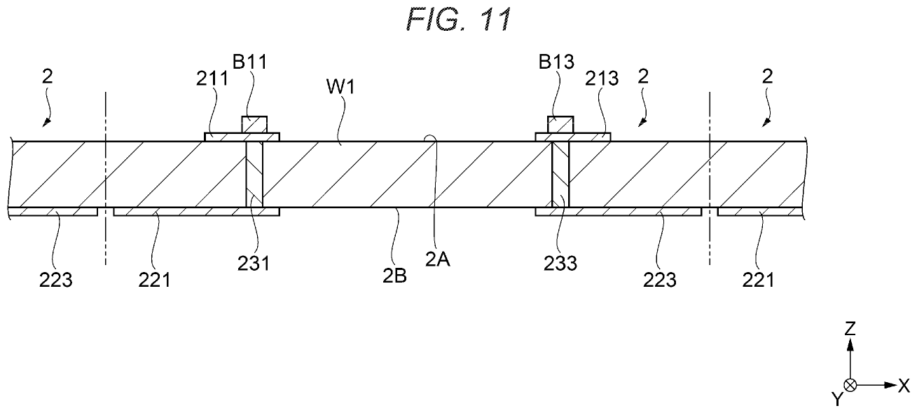

As shown in FIG. 11, in the first bonding member disposing step S5, the first bonding members B11, B12, B13, and B14 are disposed at the first surface 2A of the base 2. Specifically, the first bonding members B12 and B14 as shown in FIGS. 3 and 4 and the first bonding members B11 and B13 as shown in FIG. 11 are disposed at the first surface 2A of the base 2. More specifically, metal bumps as the first bonding members B11, B12, B13, and B14 are disposed on upper surfaces of the base electrodes 211, 212, 213, and 214 provided on the first surface 2A of the base 2 by using a known technique such as a ball wire bonding technique or a printing technique.

In the present embodiment, the first bonding members B11 and B12 are disposed to overlap the second bonding members B21 and B22 in the plan view in the vibrator element bonding step S10 to be described later, but a disposition of the first bonding members B11, B12, B13, and B14 is not limited thereto. For example, the first bonding members B13 and B14 may be disposed to overlap the second bonding members B21 and B22 in the vibrator element bonding step S10.

### Second Bonding Member Disposing Step S6

The second bonding member disposing step S6 is a step of disposing the second bonding members B21 and B22 on the fourth surface 3B of the circuit element 3.

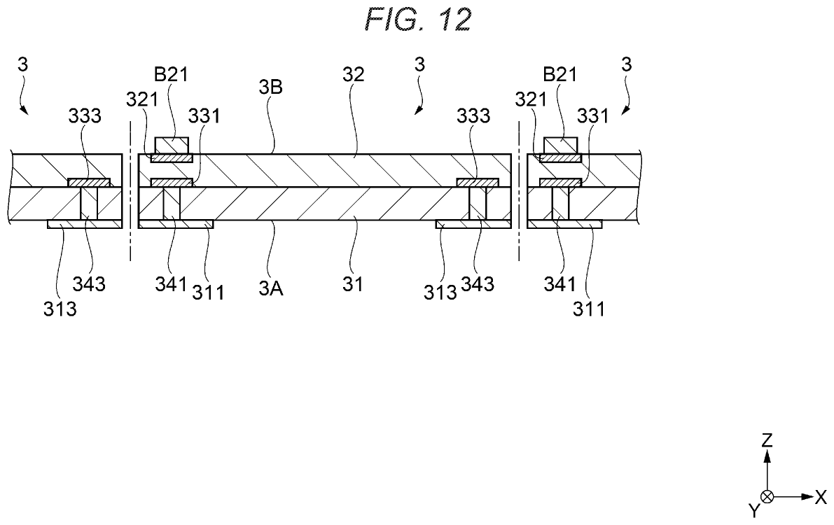

As shown in FIG. 12, in the second bonding member disposing step S6, the second bonding members B21 and B22 are disposed on the fourth surface 3B of the circuit element 3. Specifically, the second bonding member B22 shown in FIGS. 2 and 3 and the second bonding member B21 shown in FIG. 12 are disposed on the fourth surface 3B of the circuit element 3. More specifically, metal bumps as the second bonding members B21 and B22 are disposed on upper surfaces of the second element electrodes 321 and 322 provided on the fourth surface 3B of the circuit element 3 by using a known technique such as a ball wire bonding technique or a printing technique.

In the present embodiment, the second bonding members B21 and B22 are disposed to overlap the first bonding members B11 and B12 in the plan view in the vibrator element bonding step S10 to be described later, but a disposition of the second bonding members B21 and B22 is not limited thereto. For example, the second bonding members B21 and B22 may be disposed to overlap the first bonding members B13 and B14, in the vibrator element bonding step S10.

In the present embodiment, as shown in FIG. 12, the plurality of circuit elements 3 are diced by using a known technique such as a dicing technique or an etching technique after completion of the second bonding member disposing step S6.

### Circuit Element Disposing Step S7

The circuit element disposing step S7 is a step of disposing the circuit element 3 having the third surface 3A and the fourth surface 3B in a front-back relationship with the third surface 3A at the first surface 2A side of the base 2.

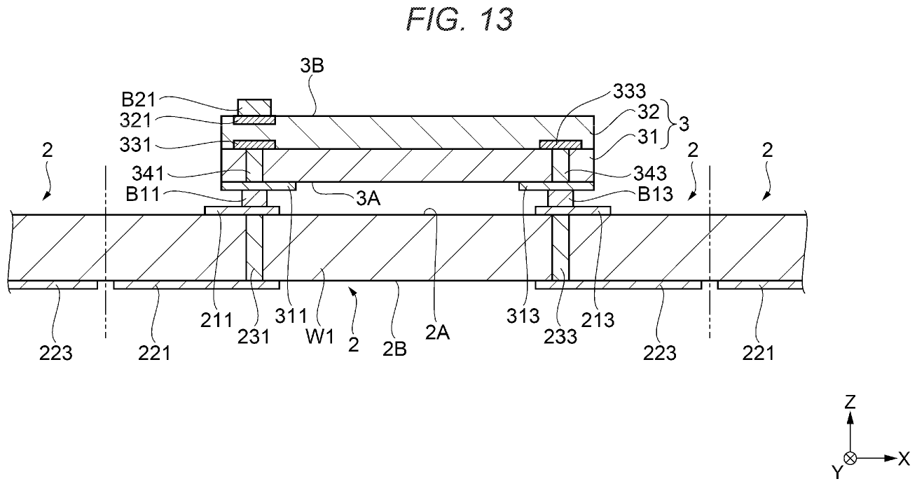

As shown in FIG. 13, in the circuit element disposing step S7, the circuit element 3 is disposed at the first surface 2A side of the base 2. The third surface 3A of the circuit element 3 is disposed to face the first surface 2A of the base 2. In this manner, the circuit element 3 is disposed such that the first element electrodes 311, 312, 313, and 314 provided on the third surface 3A of the circuit element 3 and the base electrodes 211, 212, 213, and 214 provided on the first surface 2A of the base 2 face each other while metal bumps as the first bonding members B11, B12, B13, and B14 are interposed therebetween. Specifically, the circuit element 3 is disposed such that the first element electrodes 311 and 313 and the base electrodes 211 and 213 as shown in FIG. 13 respectively face each other while the first bonding members B11 and B13 are interposed therebetween, and the first element electrodes 312 and 314 and the base electrodes 212 and 214 as shown in FIGS. 3 and 5 respectively face each other while the first bonding members B12 and B14 are interposed therebetween.

### Circuit Element Bonding Step S8

The circuit element bonding step S8 is a step of bonding the circuit element 3 to the base 2 via the first bonding members B11, B12, B13, and B14.

In the circuit element bonding step S8, the circuit element 3 is bonded to the base 2 via metal bumps as the first bonding members B11, B12, B13, and B14 by using a known technique such as an ultrasonic bonding technique or a thermocompression bonding technique. Specifically, the first element electrodes 311, 312, 313, and 314 provided on the third surface 3A of the circuit element 3 and the base electrodes 211, 212, 213, and 214 provided on the first surface 2A of the base 2 are bonded to each other via metal bumps as the first bonding members B11, B12, B13, and B14, respectively.

### Vibrator Element Disposing Step S9

The vibrator element disposing step S9 is a step of disposing the vibrator element 4 at the fourth surface 3B side of the circuit element 3.

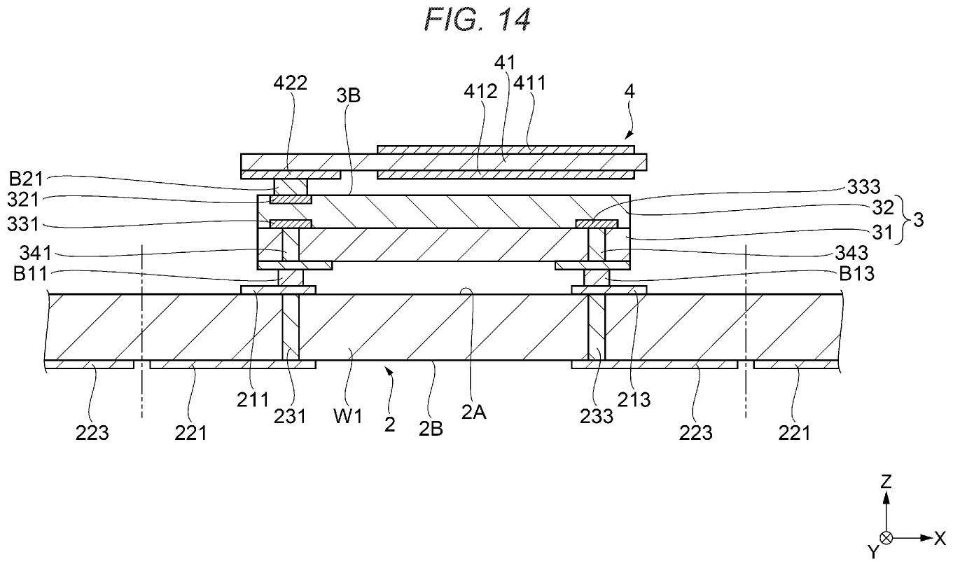

As shown in FIG. 14, in the vibrator element disposing step S9, the vibrator element 4 is disposed at the fourth surface 3B side of the circuit element 3. The vibrator element 4 is disposed to overlap the circuit element 3 in the plan view. In this manner, the vibrator element 4 is disposed such that the coupling electrode 422 of the vibrator element 4 provided on the surface facing the fourth surface 3B and the second element electrode 321 provided on the fourth surface 3B of the circuit element 3 face each other while a metal bump as the second bonding member B21 is interposed therebetween. Similarly, as shown in FIGS. 2 and 3, the vibrator element 4 is disposed such that the coupling electrode 421 of the vibrator element 4 provided on the surface facing the fourth surface 3B and the second element electrode 322 provided on the fourth surface 3B of the circuit element 3 face each other while a metal bump as the second bonding member B22 is interposed therebetween.

### Vibrator Element Bonding Step S10

The vibrator element bonding step S10 is a step of bonding the vibrator element 4 to the circuit element 3 via the second bonding members B21 and B22.

In the vibrator element bonding step S10, the vibrator element 4 is bonded to the circuit element 3 via metal bumps as the second bonding members B21 and B22 by using a known technique such as an ultrasonic bonding technique or a thermocompression bonding technique. Specifically, the coupling electrode 422 of the vibrator element 4 provided on the surface facing the fourth surface 3B and the second element electrode 321 provided on the fourth surface 3B of the circuit element 3 are bonded to each other via a metal bump as the second bonding member B21. The coupling electrode 421 of the vibrator element 4 provided on the surface facing the fourth surface 3B and the second element electrode 322 provided on the fourth surface 3B of the circuit element 3 are bonded to each other via a metal bump as the second bonding member B22.

In the present embodiment, as described above, the first bonding members B11 and B12 respectively overlap the second bonding members B21 and B22 in the plan view of the circuit element 3. Therefore, in the vibrator element bonding step S10, the circuit element 3 is supported from below by the first bonding members B11 and B12 against the pressing force for pressing the second bonding members B21 and B22, and the bending of the circuit element 3 is prevented. By preventing the bending of the circuit element 3, it is possible to effectively press the second bonding members B21 and B22. Therefore, it is possible to provide the vibrator device 1 in which the bonding reliability between the circuit element 3 and the vibrator element 4 is improved.

### Lid Bonding Step S11

The lid bonding step S11 is a step of forming the cavity 6 that accommodates the circuit element 3 and the vibrator element 4 by bonding the lid 5 to the base 2.

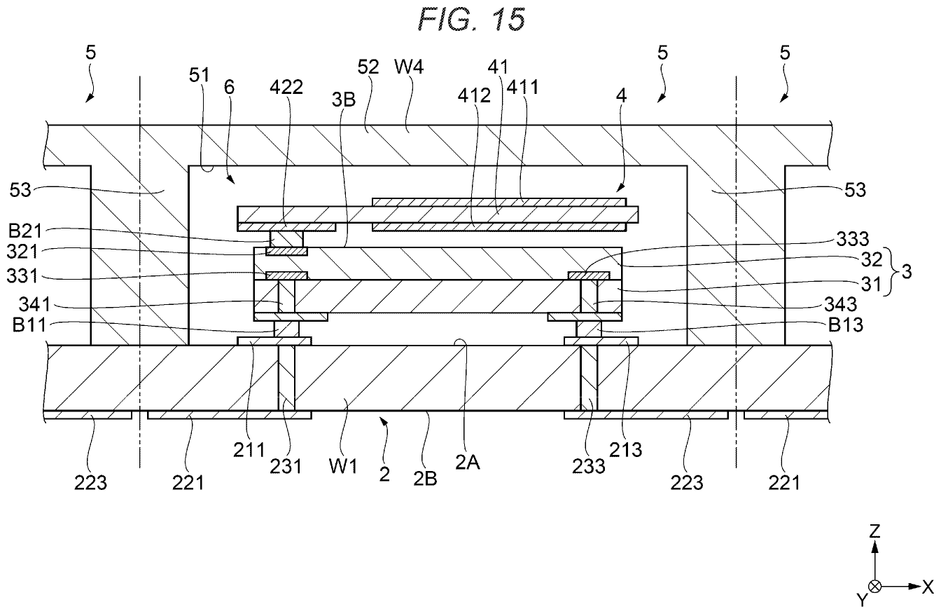

As shown in FIG. 15, in the lid bonding step S11, the base 2 formed as the large silicon substrate W1 and the lid 5 formed as the large silicon substrate W4 are bonded to each other under a depressurized atmosphere. Specifically, first, the lid 5 is disposed such that the circuit element 3 and the vibrator element 4 that are stacked at the first surface 2A side of the base 2 are accommodated in the recessed portion 51 of the lid 5. Next, the lid 5 is bonded to the first surface 2A of the base 2 so as to close the opening portion of the recessed portion 51. In this manner, the cavity 6 that accommodates the circuit element 3 and the vibrator element 4 is formed between the base 2 and the lid 5.

In the present embodiment, the large silicon substrate W1 is bonded to the large silicon substrate W4 such that a plurality of vibrator devices 1 are formed in a coupling state.

After the completion of the lid bonding step S11, the base 2 may be thinned by, for example, polishing a lower surface of the large silicon substrate W1. Similarly, after the completion of the lid bonding step S11, the lid 5 may be thinned by, for example, polishing an upper surface of the large silicon substrate W4. By thinning the base 2 and the lid 5, it is possible to reduce a thickness of the vibrator device 1. In the case of thinning the base 2 after the completion of the lid bonding step S11, the base through electrodes 231, 232, 233, and 234 and the external electrodes 221, 222, 223, and 224 are formed after the base 2 is thinned.

### Dicing Step S12

The dicing step S12 is a step of dicing the plurality of vibrator devices 1 formed in a coupling state.

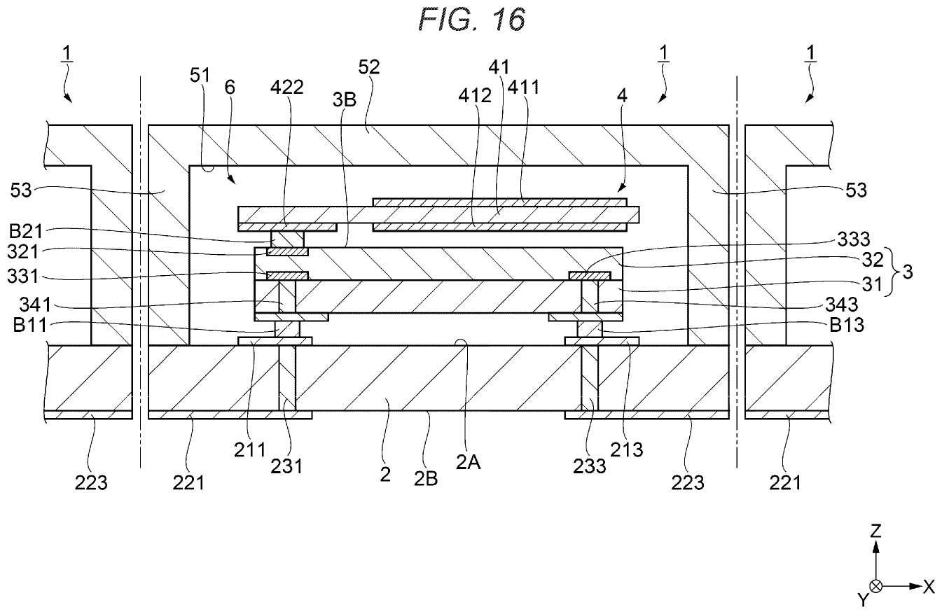

As shown in FIG. 16, in the dicing step S12, the large silicon substrate W1 and the large silicon substrate W4 in which the plurality of vibrator devices 1 are formed in a coupling state are cut by using a known technique such as a dicing technique or an etching technique. In this manner, the vibrator devices 1 are diced, and the vibrator device 1 shown in FIG. 1 is obtained.

As described above, according to the present embodiment, the following effects can be obtained.

The vibrator device 1 includes: the base 2 having the first surface 2A and the second surface 2B in a front-back relationship with each other; the circuit element 3 located at the first surface 2A side of the base 2 and having the third surface 3A at the first surface 2A side and the fourth surface 3B in a front-back relationship with the third surface 3A; the vibrator element 4 located at the fourth surface 3B side of the circuit element 3; the first bonding members B11, B12, B13, and B14 disposed between the base 2 and the circuit element 3 and bonding the base 2 to the circuit element 3; the second bonding members B21 and B22 disposed between the circuit element 3 and the vibrator element 4 and bonding the circuit element 3 to the vibrator element 4; and the lid 5 bonded to the base 2 so as to form the cavity 6 that accommodates the circuit element 3 and the vibrator element 4 between the lid 5 and the base 2, in which at least a part of the second bonding members B21 and B22 overlaps the first bonding members B11, B12, B13, and B14 in the plan view of the circuit element 3.

Accordingly, the bending of the circuit element 3 that occurs when the vibrator element 4 is bonded to the circuit element 3 is prevented, and the second bonding members B21 and B22 that bond the circuit element 3 to the vibrator element 4 can be effectively pressed. Therefore, it is possible to provide the vibrator device 1 in which the bonding reliability between the circuit element 3 and the vibrator element 4 is improved.

The method for manufacturing the vibrator device 1 is a method for manufacturing the vibrator device 1 including the base 2, the circuit element 3, the vibrator element 4, and the lid 5 bonded to the base 2 so as to form the cavity 6 that accommodates the circuit element 3 and the vibrator element 4 between the lid 5 and the base 2, and the method includes: the base preparation step S1 of preparing the base 2 having the first surface 2A and the second surface 2B in a front-back relationship with each other; the first bonding member disposing step S5 of disposing the first bonding members B11, B12, B13, and B14 at the first surface 2A of the base 2; the circuit element disposing step S7 of disposing the circuit element 3 at the first surface 2A side, the circuit element 3 having the third surface 3A located at the first surface 2A side and the fourth surface 3B in a front-back relationship with the third surface 3A; the circuit element bonding step S8 of bonding the circuit element 3 to the base 2 via the first bonding members B11, B12, B13, and B14; the second bonding member disposing step S6 of disposing the second bonding members B21 and B22 on the fourth surface 3B of the circuit element 3; the vibrator element disposing step S9 of disposing the vibrator element 4 at the fourth surface 3B side of the circuit element 3; the vibrator element bonding step S10 of bonding the vibrator element 4 to the circuit element 3 via the second bonding members B21 and B22; and the lid bonding step S11 of forming the cavity 6 that accommodates the circuit element 3 and the vibrator element 4 by bonding the lid 5 to the base 2, in which at least a part of the second bonding members B21 and B22 overlaps the first bonding members B11, B12, B13, and B14 in the plan view of the circuit element 3.

Accordingly, the bending of the circuit element 3 that occurs when the vibrator element 4 is bonded to the circuit element 3 is prevented, and the second bonding members B21 and B22 that bond the circuit element 3 to the vibrator element 4 can be effectively pressed. Therefore, it is possible to provide the vibrator device 1 in which the bonding reliability between the circuit element 3 and the vibrator element 4 is improved.

### 2. Second Embodiment

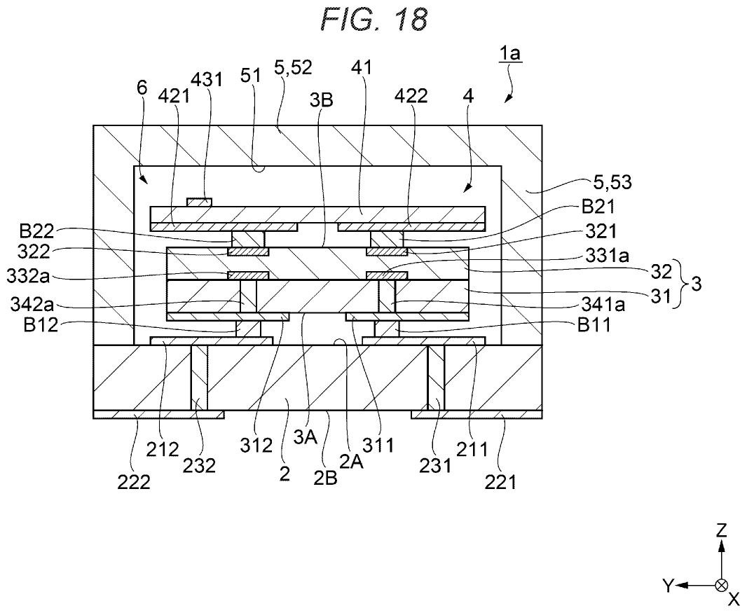

Next, a vibrator device la according to a second embodiment will be described with reference to FIGS. 17, 18, and 19.

Compared with the vibrator device 1 according to the first embodiment, the vibrator device la according to the second embodiment is the same as the vibrator device 1 according to the first embodiment except that metal bumps as the second bonding members B21 and B22 respectively overlap element through electrodes 341a and 342a and the second element electrodes 321 and 322 respectively overlap third element electrodes 331a and 332a in a plan view of the circuit element 3.

The same components as those of the first embodiment described above are denoted by the same reference numerals, and the description thereof will be omitted.

As shown in FIGS. 17, 18, and 19, in the present embodiment, the metal bumps as the second bonding members B21 and B22 respectively overlap the element through electrodes 341a and 342a in the plan view. The second element electrodes 321 and 322 electrically coupled to the second bonding members B21 and B22 respectively overlap the third element electrodes 331a and 332a electrically coupled to the element through electrodes 341a and 342a. The second element electrodes 321 and 322 are provided on an upper surface of the circuit unit 32, and the third element electrodes 331a and 332a are provided on a lower surface of the circuit unit 32.

The circuit unit 32 includes various circuits such as an oscillation circuit that oscillates the vibrator element 4 and generates an output signal such as a clock signal, but there is a problem that these circuits cannot be disposed in a region overlapping the second bonding members B21 and B22 or a region overlapping the element through electrodes 341a, 342a, 343, and 344 in the plan view. Specifically, for example, when a circuit is disposed in the region overlapping the second bonding members B21 and B22 in the plan view in the circuit unit 32, the circuit unit 32 is pressed via the second bonding members B21 and B22 when bonding the vibrator element 4 to the circuit element 3, and characteristics of the circuit disposed in the region overlapping the second bonding members B21 and B22 may change. In addition, for example, when a circuit is disposed in the region overlapping the element through electrodes 341a, 342a, 343, and 344 in the plan view in the circuit unit 32, characteristics of the circuit disposed in the region overlapping the element through electrodes 341a, 342a, 343, and 344 may change due to a stress generated by a difference in thermal expansion coefficient between the element through electrodes 341a, 342a, 343, and 344 and the base 2 or the circuit unit 32.

Therefore, in the present embodiment, no circuit is disposed in the region overlapping the second bonding members B21 and B22 and the region overlapping the element through electrodes 341a, 342a, 343, and 344 in the plan view in the circuit unit 32.

In the present embodiment, since the second bonding members B21 and B22 respectively overlap the element through electrodes 341a and 342a in the plan view, it is possible to reduce the number of regions in which no circuit can be disposed in the circuit unit 32 in the plan view as compared with the first embodiment. That is, by respectively overlapping the second bonding members B21 and B22 and the element through electrodes 341a and 342a in the plan view, it is possible to reduce a size of the circuit element 3 as compared with the first embodiment.

In FIG. 19, in the plan view, a part of the second bonding members B21 and B22 respectively overlaps the entire element through electrodes 341a and 342a. Alternatively, the entire second bonding members B21 and B22 may respectively overlap a part of the element through electrodes 341a and 342a. The entire second bonding members B21 and B22 may overlap the entire element through electrodes 341a and 342a. A part of the second bonding members B21 and B22 may overlap a part of the element through electrodes 341a and 342a.

In other words, at least a part of the second bonding members B21 and B22 may overlap the element through electrodes 341a and 342a in the plan view of the circuit element 3.

As described above, according to the present embodiment, the following effects can be obtained in addition to the effects according to the first embodiment.

When at least a part of the second bonding members B21 and B22 overlaps the element through electrodes 341a and 342a in the plan view, it is possible to reduce the number of regions in which no circuit is disposed in the circuit unit 32 and to reduce the size of the circuit element 3.

### 3. Third Embodiment

Next, a method for manufacturing the vibrator device 1 according to a third embodiment will be described with reference to FIGS. 20 to 24.

Compared with the method for manufacturing the vibrator device 1 according to the first embodiment, the method for manufacturing the vibrator device 1 according to the third embodiment is the same as that according to the first embodiment except that the method includes a step of disposing the second bonding members B21 and B22 on the vibrator element 4 instead of the step of disposing the second bonding members B21 and B22 on the fourth surface 3B of the circuit element 3.

The same components as those of the first embodiment described above are denoted by the same reference numerals, and the description thereof will be omitted.

As shown in FIG. 20, the method for manufacturing the vibrator device 1 includes the base preparation step S1, a circuit element preparation step S2b, a vibrator element preparation step S3b, the lid preparation step S4, the first bonding member disposing step S5, a second bonding member disposing step S6b, the circuit element disposing step S7, the circuit element bonding step S8, the vibrator element disposing step S9, the vibrator element bonding step S10, the lid bonding step S11, and the dicing step S12.

Specifically, first, in the base preparation step S1, the circuit element preparation step S2b, the vibrator element preparation step S3b, and the lid preparation step S4, the base 2, the circuit element 3, the vibrator element 4, and the lid 5 are respectively prepared. Next, the base 2 prepared in the base preparation step S1 and the vibrator element 4 prepared in the vibrator element preparation step S3b are respectively moved to the first bonding member disposing step S5 and the second bonding member disposing step S6b. Next, the base 2 at which the first bonding members B11, B12, B13, and B14 are disposed in the first bonding member disposing step S5 and the circuit element 3 prepared in the circuit element preparation step S2b are moved to the circuit element disposing step S7. After completion of the circuit element disposing step S7, the method proceeds to the circuit element bonding step S8. Next, the circuit element 3 and the base 2 that are bonded via the first bonding members B11, B12, B13, and B14 in the circuit element bonding step S8 and the vibrator element 4 on which the second bonding members B21 and B22 are disposed in the second bonding member disposing step S6b are moved to the vibrator element disposing step S9. After completion of the vibrator element disposing step S9, the method proceeds to the vibrator element bonding step S10. Next, the base 2, the circuit element 3 bonded to the base 2 via the first bonding members B11, B12, B13, and B14, the vibrator element 4 bonded to the circuit element 3 via the second bonding members B21 and B22 in the vibrator element bonding step S10, and the lid 5 prepared in the lid preparation step S4 are moved to the lid bonding step S11. After completion of the lid bonding step S11, the process proceeds to the dicing step S12. In this manner, the vibrator device 1 shown in FIG. 1 can be obtained.

Hereinafter, these steps will be described in order.

### Base Preparation Step S1

Since the base preparation step S1 is the same as that according to the first embodiment, the description thereof will be omitted.

### Circuit Element Preparation Step S2b

The circuit element preparation step S2b is similar to that of the first embodiment in that the circuit unit 32 is formed on the large silicon substrate W2 serving as a base material of the element substrate 31, and the first element electrodes 311, 312, 313, and 314, the second element electrodes 321 and 322, the third element electrodes 331, 332, 333, and 334, and the element through electrodes 341, 342, 343, and 344 are formed.

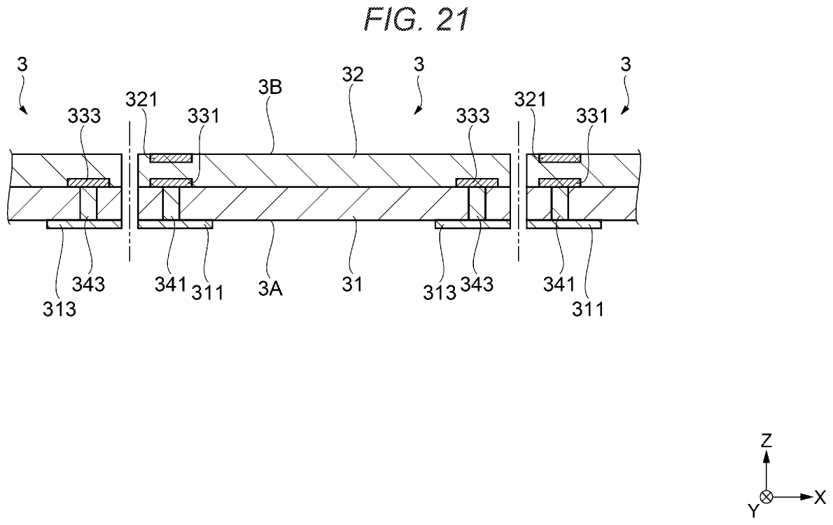

In the present embodiment, as shown in FIG. 21, after completion of the circuit element preparation step S2b, a plurality of circuit elements 3 formed as the large silicon substrate W2 are diced by using a known technique such as a dicing technique or an etching technique.

### Vibrator Element Preparation Step S3b

The vibrator element preparation step S3b is similar to that of the first embodiment in that the excitation electrodes 411 and 412, the coupling electrodes 421 and 422, and the lead-out wires 431 and 432 are formed on the large quartz crystal substrate W3 serving as a base material of the vibrator substrate 41.

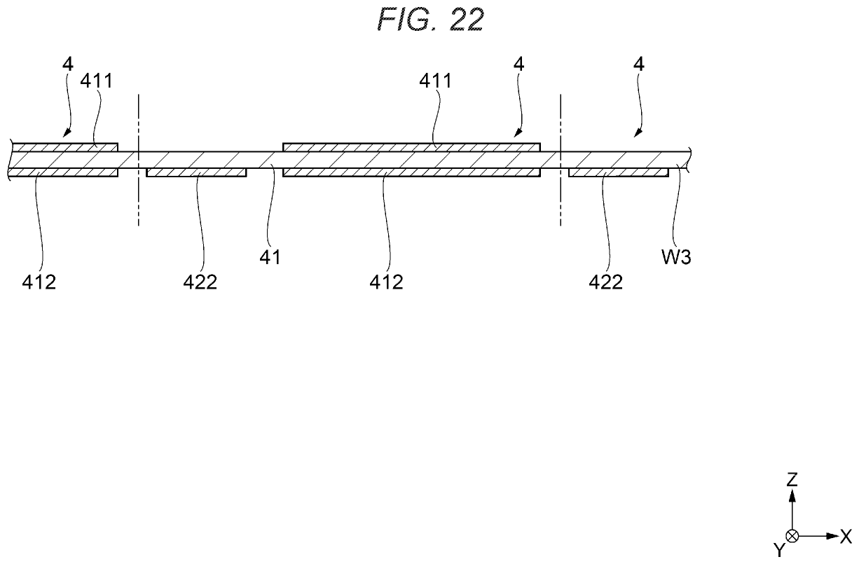

In the present embodiment, as shown in FIG. 22, after completion of the vibrator element preparation step S3b, a plurality of vibrator elements 4 formed as the large quartz crystal substrate W3 are in a coupling state. The plurality of vibrator elements 4 formed as the large quartz crystal substrate W3 are diced after completion of the second bonding member disposing step S6b to be described later.

### Lid Preparation Step S4 and First Bonding Member Disposing Step S5

Since the lid preparation step S4 and the first bonding member disposing step S5 are the same as those according to the first embodiment, the description thereof will be omitted.

### Second Bonding Member Disposing Step S6b

The second bonding member disposing step S6b is a step of disposing the second bonding members B21 and B22 on the vibrator element 4. Similar to the first embodiment, the second bonding members B21 and B22 are disposed to overlap the first bonding members B11 and B12 in a plan view in the vibrator element bonding step S10.

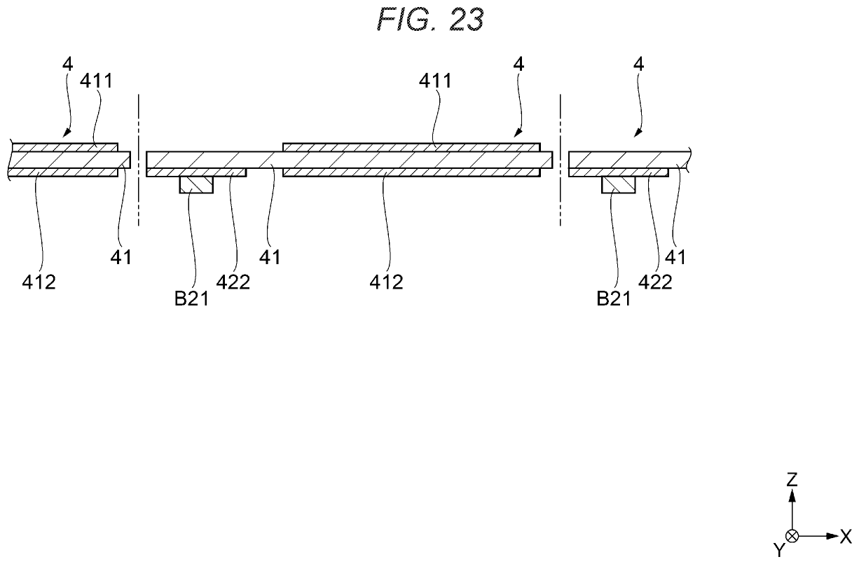

As shown in FIG. 23, the second bonding members B21 and B22 are disposed on the vibrator element 4 in the second bonding member disposing step S6b. Specifically, the second bonding member B21 is disposed on a lower surface of the coupling electrode 422 of the vibrator element 4 by using a known technique such as a ball wire bonding technique or a printing technique. Similarly, as shown in FIGS. 2 and 3, the second bonding member B22 is disposed on a lower surface of the coupling electrode 421 of the vibrator element 4.

In the present embodiment, as shown in FIG. 23, after the completion of the second bonding member disposing step S6b, the plurality of vibrator elements 4 are diced by using a known technique such as a dicing technique or an etching technique.

### Circuit Element Disposing Step S7

Since the circuit element disposing step S7 is the same as that according to the first embodiment, the description thereof will be omitted.

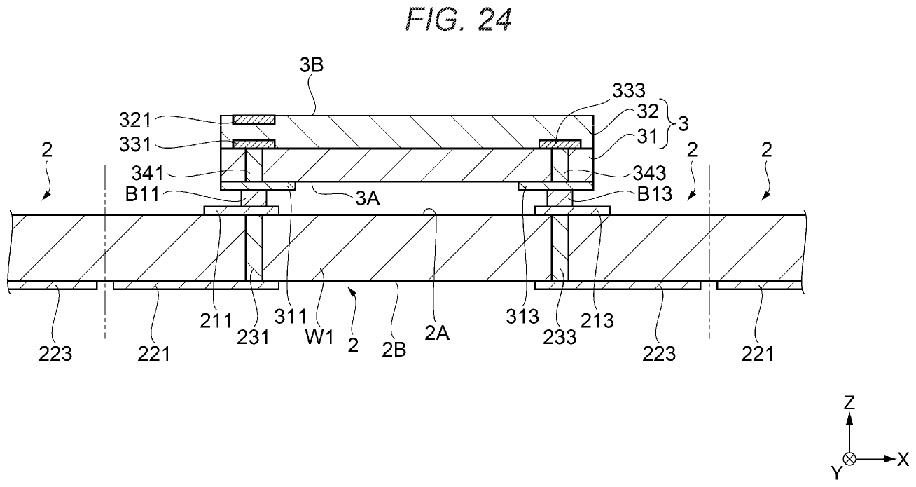

In the circuit element disposing step S7, the circuit element 3 is disposed at the first surface 2A side of the base 2 as shown in FIG. 24. When the circuit element disposing step S7 is completed, the method proceeds to the circuit element bonding step S8.

Since the circuit element bonding step S8 and steps S9 to S12 after the circuit element bonding step S8 are the same as those according to the first embodiment, the description thereof will be omitted.

As described above, the vibrator device 1 shown in FIG. 1 is obtained.

As described above, according to the present embodiment, the following effects can be obtained.

The method for manufacturing the vibrator device 1 is a method for manufacturing the vibrator device 1 including the base 2, the circuit element 3, the vibrator element 4, and the lid 5 bonded to the base 2 so as to form the cavity 6 that accommodates the circuit element 3 and the vibrator element 4 between the lid 5 and the base 2, and the method includes: the base preparation step S1 of preparing the base 2 having the first surface 2A and the second surface 2B in a front-back relationship with each other; the first bonding member disposing step S5 of disposing the first bonding members B11, B12, B13, and B14 at the first surface 2A of the base 2; the circuit element disposing step S7 of disposing the circuit element 3 at the first surface 2A side, the circuit element 3 having the third surface 3A located at the first surface 2A side and the fourth surface 3B in a front-back relationship with the third surface 3A; the circuit element bonding step S8 of bonding the circuit element 3 the base 2 via the first bonding members B11, B12, B13, and B14; the second bonding member disposing step S6b of disposing the second bonding members B21 and B22 on the vibrator element 4; the vibrator element disposing step S9 of disposing the vibrator element 4 at the fourth surface 3B side of the circuit element 3; the vibrator element bonding step S10 of bonding the vibrator element 4 to the circuit element 3 via the second bonding members B21 and B22; and the lid bonding step S11 of forming the cavity 6 that accommodates the circuit element 3 and the vibrator element 4 by bonding the lid 5 to the base 2, in which at least a part of the second bonding members B21 and B22 overlaps the first bonding members B11, B12, B13, and B14 in the plan view of the circuit element 3.

Accordingly, the same effects as those according to the first embodiment can be obtained.

The vibrator devices 1 and la are described above based on the first embodiment and the second embodiment. The method for manufacturing the vibrator device 1 is described based on the first embodiment and the third embodiment. However, the present disclosure is not limited thereto, and a configuration of each unit can be replaced with any configuration having the same function. Any other components may be added to the present disclosure. The embodiments may be appropriately combined.

For example, the second embodiment and the third embodiment may be combined.

For example, the method for manufacturing the vibrator device 1 according to the first embodiment includes the first bonding member disposing step S5 of disposing the first bonding members B11, B12, B13, and B14 at the first surface 2A of the base 2, and may also include a step of disposing the first bonding members B11, B12, B13, and B14 on the third surface 3A of the circuit element 3 instead of the first bonding member disposing step S5.

Further, for example, in the method for manufacturing the vibrator device 1 according to the first embodiment, the circuit element disposing step S7 of disposing the circuit element 3 at the first surface 2A side of the base 2 and the circuit element bonding step S8 of bonding the circuit element 3 to the base 2 are performed after the second bonding member disposing step S6 of disposing the second bonding members B21 and B22 on the fourth surface 3B of the circuit element 3. Alternatively, the second bonding member disposing step S6 of disposing the second bonding members B21 and B22 on the fourth surface 3B of the circuit element 3 may be performed after the circuit element disposing step S7 and the circuit element bonding step S8.

What is claimed is:

1. A vibrator device comprising:
a base having a first surface and a second surface in a front-back relationship with each other;
a circuit element located at a first surface side of the base and having a third surface at the first surface side and a fourth surface in a front-back relationship with the third surface;
a vibrator element located at a fourth surface side of the circuit element;
a first bonding member disposed between the base and the circuit element and configured to bond the base to the circuit element;
a second bonding member disposed between the circuit element and the vibrator element and configured to bond the circuit element to the vibrator element; and
a lid bonded to the base so as to form a cavity that accommodates the circuit element and the vibrator element between the lid and the base, wherein
at least a part of the second bonding member overlaps the first bonding member in a plan view of the circuit element.

2. The vibrator device according to claim 1, wherein
the base includes a base electrode on the first surface,
the circuit element includes a first element electrode on the third surface and a second element electrode on the fourth surface,
the vibrator element includes a coupling electrode,
the first bonding member is a first metal bump configured to electrically couple the base electrode to the first element electrode, and
the second bonding member is a second metal bump configured to electrically couple the second element electrode to the coupling electrode.

3. The vibrator device according to claim 2, wherein
the circuit element includes an element through electrode configured to electrically couple the first element electrode to a circuit unit formed at the fourth surface side, and
at least a part of the second metal bump overlaps the element through electrode in the plan view.

4. The vibrator device according to claim 2, wherein
the base includes an external electrode on the second surface, and a base through electrode configured to electrically couple the external electrode to the base electrode, and
the first metal bump does not overlap the base through electrode in the plan view.

5. A method for manufacturing a vibrator device including a base, a circuit element, a vibrator element, and a lid bonded to the base so as to form a cavity that accommodates the circuit element and the vibrator element between the lid and the base, the method comprising:
preparing the base having a first surface and a second surface in a front-back relationship with each other;
disposing a first bonding member at the first surface of the base;
disposing the circuit element at a first surface side, the circuit element having a third surface located at the first surface side and a fourth surface in a front-back relationship with the third surface;
bonding the circuit element to the base via the first bonding member;
disposing a second bonding member on the fourth surface of the circuit element;
disposing the vibrator element at a fourth surface side of the circuit element;
bonding the vibrator element to the circuit element via the second bonding member; and
forming the cavity that accommodates the circuit element and the vibrator element by bonding the lid to the base, wherein
at least a part of the second bonding member overlaps the first bonding member in a plan view of the circuit element.

6. A method for manufacturing a vibrator device including a base, a circuit element, a vibrator element, and a lid bonded to the base so as to form a cavity that accommodates the circuit element and the vibrator element between the lid and the base, the method comprising:
preparing the base having a first surface and a second surface in a front-back relationship with each other;
disposing a first bonding member at the first surface of the base;
disposing the circuit element at a first surface side, the circuit element having a third surface located at the first surface side and a fourth surface in a front-back relationship with the third surface;
bonding the circuit element to the base via the first bonding member;
disposing a second bonding member on the vibrator element;
disposing the vibrator element at a fourth surface side of the circuit element;
bonding the vibrator element to the circuit element via the second bonding member; and
forming the cavity that accommodates the circuit element and the vibrator element by bonding the lid to the base, wherein
at least a part of the second bonding member overlaps the first bonding member in a plan view of the circuit element.
